(19) United States
(12) Patent Application Publication
(10) Pub. No.: US 2024/0145368 A1
(43) Pub. Date: May 2, 2024

(54) ELECTRONIC ASSEMBLY WITH POWER MODULE INTERPOSER AND METHODS OF FORMING THEREOF

(71) Applicant: Intel Corporation, Santa Clara, CA (US)

(72) Inventors: Jackson Chung Peng KONG, Tanjung Tokong (MY); Bok Eng CHEAH, Gelugor (MY); Seok Ling LIM, Kulim Kedah (MY); Jenny Shio Yin ONG, Bayan Lepas (MY); Ravindra RUDRARAJU, Eldorado Hills, CA (US); Vijay KASTURI, Folsom, CA (US)

(21) Appl. No.: 17/975,662

(22) Filed: Oct. 28, 2022

(51) Int. Cl. H01L 23/498; H01L 21/48; H01L 23/00; H01L 25/00; H01L 25/065; H01L 25/18

(52) U.S. Cl. CPC H01L 23/49838; H01L 21/486; H01L 23/49827; H01L 23/49833; H01L 23/49894; H01L 24/16; H01L 24/17; H01L 25/0655; H01L 25/18; H01L 25/50; H01L 24/81; H01L 2224/16227; H01L 2224/16238; H01L 2224/1703; H01L 2224/81203; H01L 2224/81815; H01L 2924/1432; H01L 2924/14361

(57) ABSTRACT

The present disclosure is directed to an electronic assembly and method of forming thereof. The electronic assembly may include a package substrate with a top substrate surface and an interposer coupled to the package substrate at the top substrate surface. The interposer may include a plurality of through interposer vias and an opening extending through the interposer. A power module may be arranged in the opening in the interposer and coupled to the package substrate at the top substrate surface. The power module may include a plurality of interconnects including a first interconnect coupled to a first voltage and a second interconnect coupled to a second voltage.

### BACKGROUND

Increasing power integrity requirements for high performance computing device such as a silicon chiplet or disaggregation architecture on a 2.5D stacked package are constant challenges in advanced electronic or semiconductor packages. For example, in a 2.5D packaging architecture, the stacked package includes a combination of silicon tiles or chiplets, such as computing and graphics silicon tiles in a non-limiting example. Each of the silicon tiles or chiplets of the package demand robust power delivery network (PDN) for improved processing capabilities.

Conventional techniques to cope with the increasing power integrity requirements include increasing package substrate layer count such as providing additional power planes (Vcc) and/or ground reference planes (Vss) in the package substrate. These techniques may be employed to meet the power integrity and/or power supply noise induced jitter (PSIJ) performance target and to achieve stringent DC resistance and AC loop inductance for improved device performance. Other techniques include reduction of silicon current carrying capacity, ICCMax threshold and/or increased total count of TSV interconnects to mitigate device reliability risks.

However, the above-mentioned solutions may result in increased silicon and/or package substrate footprint expansion due to additional interconnects and/or layer count, which inhibits device form-factor miniaturization, as well as trade-offs to device performance, such as reduced maximum frequency (Fmax) threshold for the computing and/or graphic cores.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIGS. 1A and 1B show cross-section and top views, respectively, of an exemplary electronic assembly according to an aspect of the present disclosure;

FIGS. 2A and 2B show cross-section and top views, respectively, of another exemplary electronic assembly according to an aspect of the present disclosure;

FIGS. 3A through 3E illustrate cross-section views of a process of forming the electronic assembly according to an aspect of the present disclosure;

FIGS. 4A through 4D illustrate bottom and top views of an interposer through the process for forming the electronic assembly shown in FIGS. 3A through 3D; and

FIG. 5 shows a simplified flow diagram for an exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

The present disclosure is directed to an electronic or semiconductor assembly or package that provides power modules through an interposer of the electronic assembly for improved computing performance and device miniaturization. According to various embodiments, the interposer of the electronic assembly may include a plurality of through interposer vias and an opening extending through the interposer. A power module may be arranged in the opening in the interposer. The power module may include a plurality of interconnects including a first interconnect coupled to a first voltage and a second interconnect coupled to a second voltage. For example, the first voltage may be, or include, a reference voltage, and the second voltage may be, or include, a power supply voltage. The interposer and the power module may be coupled to a top substrate surface of a package substrate.

A technical advantage of the present disclosure includes providing improved electrical (power integrity) performance through streamlined and localized power delivery network (PDN) using the power module(s) in the interposer for electronic assemblies, such as 2.5D or 3D stacked die packages. The power module(s) provide increased geometry or area of the interconnects or power delivery network, which reduces resistance and facilitates enhanced power delivery network (PDN) requirements for improved device performance.

According to various embodiments, the first interconnect and the second interconnect may each include a plurality of conductive planes extending horizontally in layers between a top surface and a bottom surface of the power module. Another technical advantage of the present disclosure includes improved alternating current (AC) loop inductance through the tightly coupled Vcc-Vss network within the power module(s).

Further, reduced direct current (DC) resistance may be achieved through increased thickness (e.g., 30 μm or greater) and/or total volume of the conductive planes associated to power (e.g., which may be interchangeably referred to as power plane herein), without being restricted by conventional package manufacturing assembly process, i.e., homogenous metal layer thickness (approximately 15 μm) across signal routing and the power delivery network in a package substrate.

A further technical advantage of the present disclosure includes improved device reliability by increased Imax capacity through reduced DC resistance, which may be achieved through enhanced geometry of the power module interconnect (e.g., increased thickness and/or volume geometry of the power module interconnect). The increased Imax threshold, for example, allows higher power rating and performance for the computing and graphic tiles.

Further, device miniaturization may be achieved through reduction of silicon and/or footprint of the package substrate, such as metal layer count reduction for metal layers associated to power, by providing the localized power module and power delivery network in the interposer.

To more readily understand and put into practical effect the present power module interposer of the electronic assembly and methods, which may be used for electronic assemblies, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

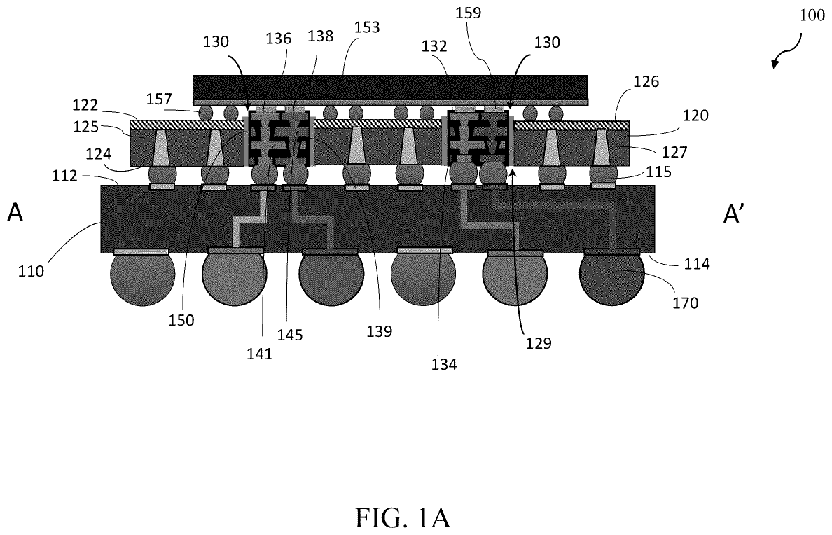

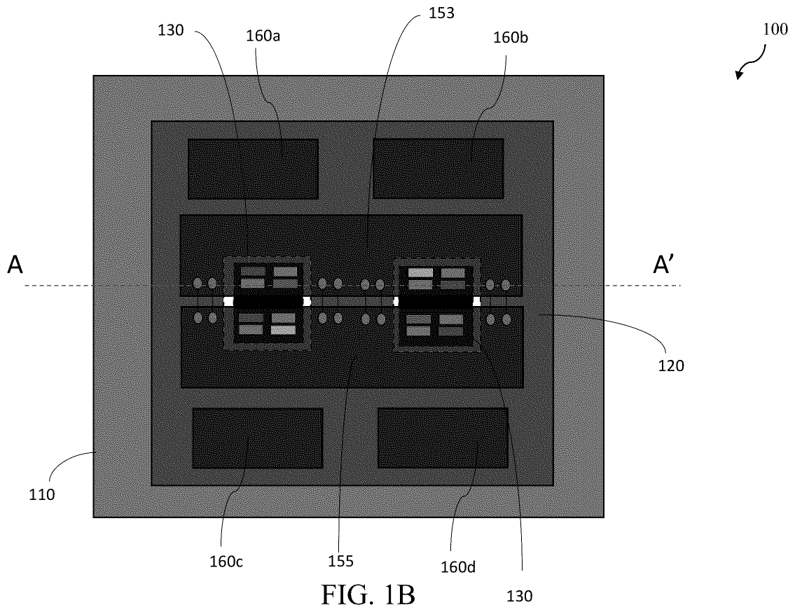

FIG. 1A shows a cross-section of an exemplary electronic assembly 100 according to an aspect of the present disclosure. FIG. 1B shows a top view of the exemplary electronic assembly 100 according to an aspect of the present disclosure. FIG. 1A shows a cross-section view along the section line A-A′ shown in FIG. 1B. According to various embodiments, the electronic assembly 100 includes a package substrate 110 with a top substrate surface 112. The package substrate 110 may include signal routings.

An interposer 120 may be coupled to the package substrate 110 at the top substrate surface 112. The interposer 120 may be bonded to the package substrate 110 by solder bumps 115. The solder bumps 115 may provide coupling between the interposer 120 and the package substrate 110. An underfill (not shown) may surround the solder bumps 115 and space between the interposer 120 and the package substrate 110.

The interposer 120 may have a top surface 122 and a bottom surface 124. The interposer 120 may include a substrate 125, such as a silicon substrate or a glass substrate in a non-limiting example. In an aspect, the substrate 125 may be, or include, an organic substrate, such as but not limited to, epoxy mold compound, Bismaleimide-Triazine epoxy resin or silicone. In another aspect, the substrate 125 may be, or include, a ceramic substrate, for example, over semiconducting material (e.g., silicon). A redistribution layer 126 may be disposed on the substrate 125. The redistribution layer 126 may include one or more metal routing layers isolated by dielectric material. The metal routing layers may be provided for routing electrical signals. For example, each metal routing layers may have a thickness of about 1 μm to about 5 μm. The dielectric material of the redistribution layer 126 may be, or include, polyimide, silicate, siloxane. The redistribution layer 126 may have a thickness ranging from about 10 μm to about 30 μm.

The interposer 120 may include a plurality of through interposer vias (TIVs) (e.g., a plurality of through silicon vias (TSVs)) 127 and openings 129 extending through the interposer 120. The through interposer vias 127 and the openings 129 may extend between the top and bottom surfaces 122 and 124 of the interposer 120. As shown, the through interposer vias 127 may extend through a depth of the substrate 125 to the top and bottom surfaces 122 and 124 of the interposer 120. The through interposer vias 127 may facilitate signal transmission between the package substrate 110 and semiconductor devices and/or chiplets (e.g., 153, 155, 160a, 160b, 160c, 160d shown in FIG. 1B) on the interposer 120. The openings 129 may extend through the depth of the substrate 125 and the redistribution layer 126 of the interposer 120 to the top and bottom surfaces 122 and 124 of the interposer 120. In other words, the openings 129 may extend through the top and bottom surfaces 122 and 124 of the interposer 120. Illustratively, two openings 129 are shown in the interposer 120. In other embodiments, the interposer 120 may have more than two openings 129 or less than two openings 129, such as a single opening.

According to various embodiments, power modules 130 may be arranged in respective openings 129 in the interposer 120 and coupled to the package substrate 110 at the top substrate surface 112. The interposer 120 and the power modules 130 may face the package substrate 110. Each of the power modules 130 may have a top surface 132 and a bottom surface 134. Each of the power modules 130 may include a plurality of interconnects including a first interconnect 136 coupled to a first voltage and a second interconnect 138 coupled to a second voltage. The interconnects may be metal interconnects.

In an aspect, the first voltage may be, or include, a reference voltage. In an aspect, the second voltage may be, or include, a power supply voltage.

According to various embodiments, the first interconnect 136 may include a plurality of conductive planes 141 extending horizontally in layers between the top surface 132 and the bottom surface 134 of the power modules 130. According to various embodiments, the second interconnect 138 may include a plurality of conductive planes 145 extending horizontally in layers between the top surface 132 and the bottom surface 134 of the power modules 130. The conductive planes 141 and/or 145, for example, may be formed of copper (Cu). In an aspect, the plurality of conductive planes 145 may include a first conductive plane associated to a 1.0V supply. In an aspect, the plurality of conductive planes 145 may include a second conductive plane associated to a 1.8V supply. A conductive plane may provide a larger surface area and/or volume compared to a through silicon via, thus reducing the resistance for power delivery. Further, the power modules 130 may advantageously provide higher density of metal interconnect.

According to various embodiments, the plurality of conductive planes may include a conductive plane with a thickness of 30 μm or greater.

The power modules 130 may include a mold encapsulant 139 surrounding and isolating the interconnects. The mold encapsulant 139 may be formed of a dielectric material. Accordingly, the plurality of conductive planes 141 of the first interconnect 136 may be isolated or separated from the plurality of conductive planes 145 of the second interconnect 138 by the dielectric material. The dielectric material of the mold encapsulant 139 may be epoxy mold compound, Bismaleimide-Triazine epoxy resin or silicone. The mold encapsulant 139 may have a higher rigidity compared to a layer of polyimide, silicate or siloxane. In an aspect, a dielectric constant, Dk of the mold encapsulant 139 may be lower than a dielectric constant, Dk of the dielectric material of the redistribution layer 126 of the interposer 120. In another aspect, a dielectric constant, Dk of the mold encapsulant 139 may be higher than a dielectric constant, Dk of the redistribution layer 126. In a non-limiting example, the mold encapsulant 139 may have a dielectric constant, Dk, ranging from about 2.0 to 4.5. The selection of the respective dielectric constant, Dk for the mold encapsulant 139 and the redistribution layer 126 of the interposer 120 may be based on design optimization of the respective applications. In an aspect, the dielectric constant, Dk may be comparable for both the mold encapsulant 139 and the redistribution layer 126.

In an aspect, the power modules 130 may be attached to the interposer 120 through an adhesive layer 150. Examples of suitable adhesive materials may include, but is not limited to, light curable acrylics, cationic epoxies, thermal curable acrylates, polyester resin, or polyurethane resin.

According to various embodiments, the power modules 130 may extend beyond the top surface 122 of the interposer 120. As illustrated in FIG. 1A, the top surface 132 of the power modules 130 may protrude above the top surface 122 of the interposer 120. The bottom surface 134 of the power modules 130 and the bottom surface 124 of the interposer 120 may be substantially coplanar. In other embodiments, the power modules 130 may extend beyond the bottom surface 124 of the interposer 120. For example, the bottom surface 134 of the power modules 130 may protrude below the bottom surface 124 of the interposer 120 (not shown). In an aspect, the power modules 130 may include a module thickness ranging from about 200 μm to about 1500 μm extending beyond the top surface 122 and/or the bottom surface 124 of the interposer 120, in a non-limiting example. The power modules 130 extending beyond the top surface 122 and/or the bottom surface 124 of the interposer 120 may allow increased volume/density of the metal interconnects, which facilitates enhanced power delivery network (PDN) requirements for improved device performance. In an aspect, the power modules 130 may include a module footprint ranging from about 1 mm×1 mm to about 4 mm×4 mm. In another aspect, the power modules 130 may include a module footprint ranging from about 1 mm×2 mm to about 2 mm×4 mm.

Although the interposer 120 is illustrated to have two power modules 130, it is understood that there may be more or less power modules depending on package requirements. For example, in another embodiment, the interposer 120 may have one power module arranged in one opening in the interposer die. In yet other embodiments, the interposer 120 may include more than two power modules arranged in respective openings in the interposer 120.

As illustrated in FIG. 1B, the electronic assembly 100 may further include a first semiconductor device 153 and a second semiconductor device 155. In a non-limiting example, the first semiconductor device 153 may include a central processing unit (CPU), a neural processing unit (NPU), or a deep learning processor (DLP). In a non-limiting example, the second semiconductor device 155 may include a graphic processing unit (GPU), a system-on-chip (SOC), a memory device or an I/O tile. Referring to FIGS. 1A and 1B, the first and second semiconductor devices 153 and 155, respectively, may abridge with and couple to the top surface 122 of the interposer 120 and the top surface 132 of the power modules 130. As shown, the first semiconductor device 153 and the second semiconductor device 155 may each overlap at least a portion of the interposer 120 and at least a portion of the power modules 130. The first semiconductor device 153 and the second semiconductor device 155 may be coupled to the interposer 120 through a plurality of solder bumps 157 and to the power modules 130 through a solder layer 159. The solder bumps 157 may each have a first width, and the solder layer 159 may have a second width. The second width may be greater than the first width. In an aspect, the first width may range from about 10 μm to about 80 μm. In an aspect, the second width may range from about 100 μm to about 400 μm.

The first semiconductor device 153 and the second semiconductor device 155 may be coupled to each other through the redistribution layer 126.

According to various embodiments, the electronic assembly 100 may further include a plurality of chiplets 160a-160d, such as a memory device (EIBM/DRAM), a sensor, or a power management integrated circuit (PMIC) in a non-limiting example, coupled to the first semiconductor device 153 and/or the second semiconductor device 155 through the interposer 120.

The electronic assembly 100 may further include solder balls 170 coupled to the package substrate 110 at the bottom substrate surface 114.

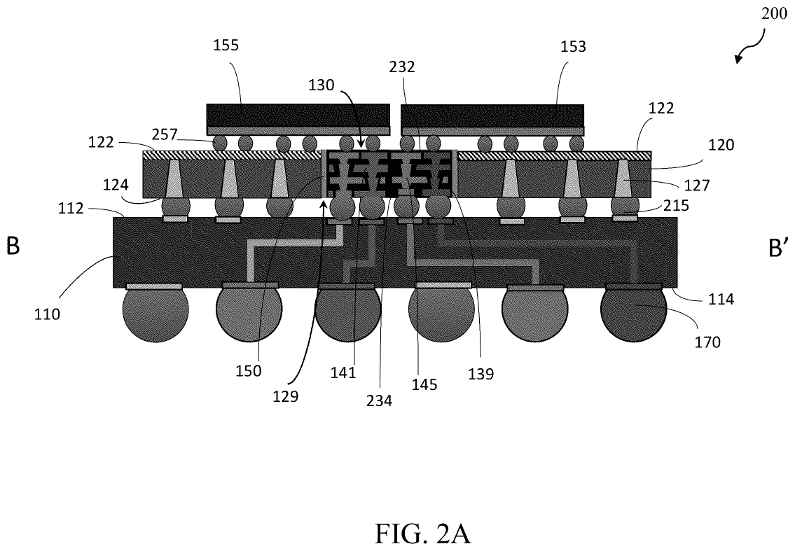

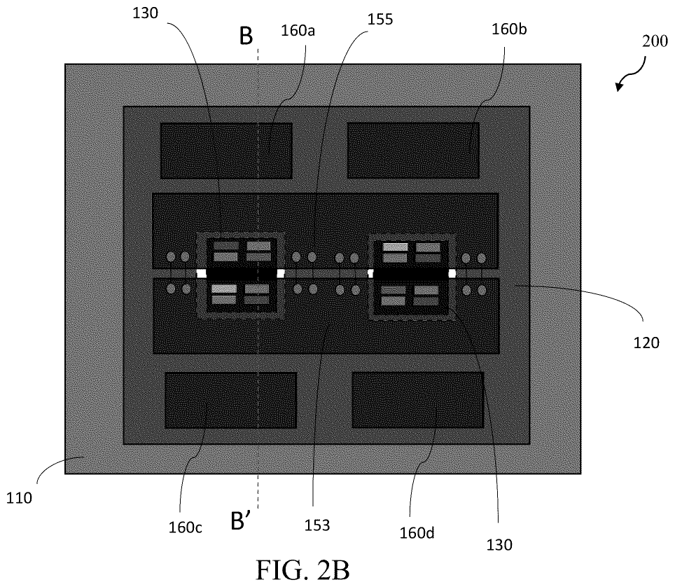

FIGS. 2A and 2B show cross-section and top views, respectively, of another exemplary electronic assembly 200 according to an aspect of the present disclosure. FIG. 2A shows a partial cross-section view along the section line B-B′ shown in FIG. 2B. The electronic assembly 200 may be similar to the electronic assembly 100. As such, common elements may not be described or described in detail in the interest of brevity. For example, the electronic assembly 200 includes the interposer 120 coupled to the package substrate 110 at the top substrate surface. The interposer 120 may include a plurality of through interposer vias 127 and openings 129 extending through the interposer 120, in which power modules 130 may be disposed. Referring to FIG. 2B, the interposer 120 may include two power modules 130, each power module being disposed in a respective opening 129.

According to various embodiments, the power modules 130 may extend between the top surface 122 and the bottom surface 124 of the interposer 120. In an aspect, the power modules 130 may extend between the top surface 122 and the bottom surface 124 of the interposer 120 to facilitate a planar configuration between the first semiconductor device 153 and the second semiconductor device 155 and the interposer 120, and between the package substrate 110 and the interposer 120 for improved manufacturability. For example, a top surface 232 of the power modules 130 and a top surface 122 of the interposer may be substantially coplanar. A bottom surface 234 of the power modules 130 and a bottom surface 124 of the interposer 120 may be substantially coplanar. In an aspect, the first semiconductor device 153 and the second semiconductor device 155 are coupled to the interposer 120 and the power modules 130 through a plurality of homogenous solder bumps 257. In an aspect, the interposer 120 is coupled to the package substrate 110 through a plurality of homogenous solder bumps 215.

In yet other embodiments, the power modules 130 may be recessed in the interposer 120.

In an aspect, the power modules 130 may include a module thickness ranging from about 100 μm to about 800 μm extending in between the top and bottom surfaces 122 and 124 of the interposer 120, in a non-limiting example.

Accordingly, various embodiments provide power module(s) in the interposer, which may include interconnects for enhanced power delivery network (PDN) requirements so as to allow improved device performance.

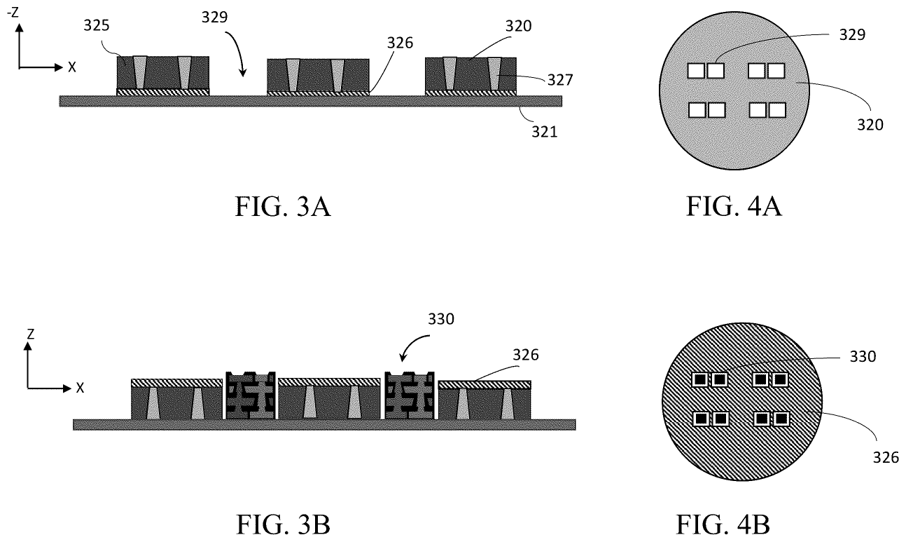

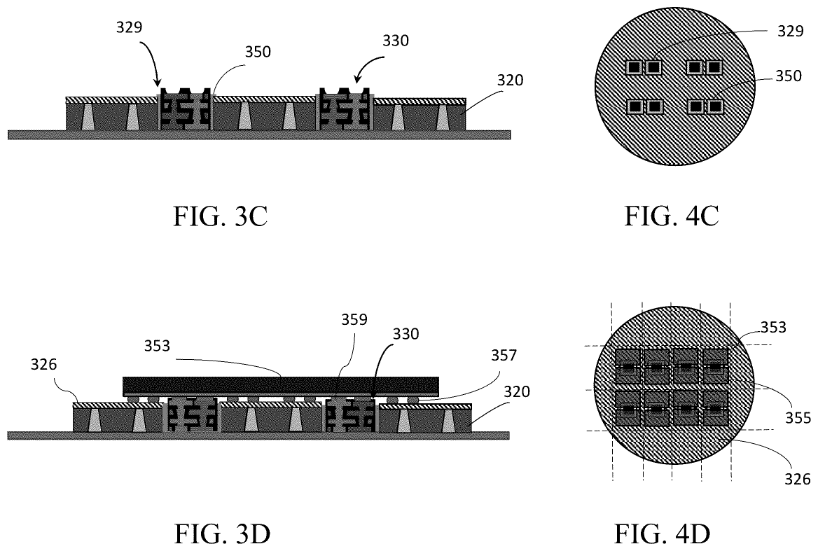

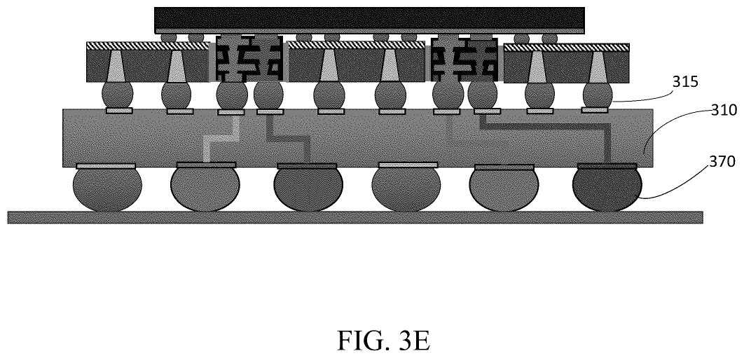

FIGS. 3A through 3E and FIGS. 4A through 4D show exemplary process for forming an electronic or semiconductor package or assembly with power modules through an interposer, according to an aspect of the present disclosure. The through interposer power modules may be provided for improved power delivery and device miniaturization. FIGS. 3A through 3E illustrate cross-section views of the process for forming the electronic assembly, while FIGS. 4A through 4D illustrate bottom and top views of the interposer through the process for forming the electronic assembly shown in FIGS. 3A through 3D.

As shown in FIG. 3A, the interposer or bridge 320 may be provided on a carrier 321. The interposer 320 may include a substrate 325 and a redistribution layer 326 disposed on the substrate. In an aspect, the interposer 320 may include a plurality of through interposer vias 327 extending through the interposer 320. The through interposer vias 327 may extend through the entire depth of the substrate 325. In an aspect, openings 329 may be formed in the interposer 320, as shown in FIG. 3A and FIG. 4A. The openings 329 may be formed by removing a portion(s) of the interposer 320, such as by mechanical drilling or a laser cutting process of portions of the substrate 325 and the redistribution layer 326, in a non-limiting example. As illustrated in FIG. 3A, the openings 329 may extend through the substrate 325 and the redistribution layer 326.

Referring to FIG. 3B, the interposer 320 may be inverted on a further carrier such that the redistribution layer 326 is facing upwards. In an aspect, power modules 330 may be positioned in respective openings 329 of the interposer 320. The power modules 330 may be positioned on the further carrier, for example by a pick and place process.

The power modules 330 may be attached to the interposer 320 using an adhesive layer 350. Referring to FIG. 3C and FIG. 4C, the adhesive layer 350 may be formed in the openings 329, such as by a dispensing or curing process in a non-limiting example.

Referring to FIG. 3D and FIG. 4D, a first semiconductor device 353 and a second semiconductor device 355 may be coupled to the interposer 320 on the redistribution layer 326 and the power modules 330. The first semiconductor device 353 and the second semiconductor device 355 may be coupled to the interposer 320 and the power modules 330 using solder bumps 357 and a solder layer 359, for example, by thermal compression bonding or a solder reflow process.

As shown in FIG. 3E, the stacked semiconductor devices and through interposer power modules may be coupled to a package substrate 310 using solder bumps 315, for example, by thermal compression bonding or a solder reflow process. Solder balls 370 may be attached to the package substrate 310.

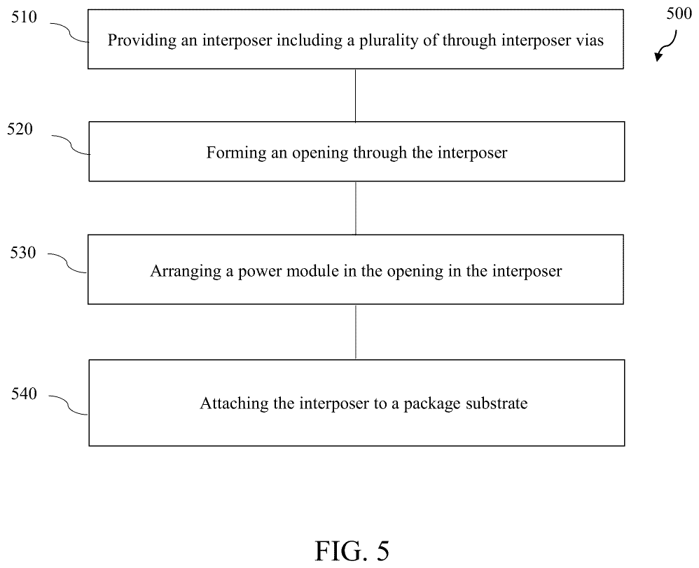

FIG. 5 shows a simplified flow diagram for an exemplary method according to an aspect of the present disclosure.

At 510, an interposer including a plurality of through interposer vias may be provided.

At 520, an opening may be formed through the interposer.

At 530, a power module may be arranged in the opening in the interposer. The power module may include a plurality of interconnects including a first interconnect coupled to a first voltage and a second interconnect coupled to a second voltage. In an aspect, the first voltage may be, or include, a reference voltage. In an aspect, the second voltage may be, or include, a power supply voltage.

At 540, the interposer may be attached to a package substrate.

To more readily understand and put into practical effect the present through interposer power module of the electronic assembly, they will now be described by way of examples. For the sake of brevity, duplicate descriptions of features and properties may be omitted.

### Examples

Example 1 provides an electronic assembly including a package substrate with a top substrate surface, an interposer coupled to the package substrate at the top substrate surface, the interposer including a plurality of through interposer vias and an opening extending through the interposer, and a power module arranged in the opening in the interposer and coupled to the package substrate at the top substrate surface, in which the power module includes a plurality of interconnects including a first interconnect coupled to a first voltage and a second interconnect coupled to a second voltage.

Example 2 may include the electronic assembly of example 1 and/or any other example disclosed herein, for which the first interconnect and/or the second interconnect includes a plurality of conductive planes extending horizontally between a top surface and a bottom surface of the power module.

Example 3 may include the electronic assembly of example 2 and/or any other example disclosed herein, for which the plurality of conductive planes of the first interconnect is isolated from the plurality of conductive planes of the second interconnect by a dielectric material.

Example 4 may include the electronic assembly of example 3 and/or any other example disclosed herein, for which the dielectric material is epoxy mold compound, Bismaleimide-Triazine epoxy resin or silicone.

Example 5 may include the electronic assembly of example 2 and/or any other example disclosed herein, for which the plurality of conductive planes comprises a conductive plane with a thickness of 30 μm or greater.

Example 6 may include the electronic assembly of example 1 and/or any other example disclosed herein, for which the power module extends between a top surface and bottom surface of the interposer.

Example 7 may include the electronic assembly of example 1 and/or any other example disclosed herein, for which the power module extends beyond a top surface of the interposer.

Example 8 may include the electronic assembly of example 1 and/or any other example disclosed herein, for which the first voltage includes a reference voltage, and wherein the second voltage includes a power supply voltage.

Example 9 may include the electronic assembly of example 1 and/or any other example disclosed herein, further including a first semiconductor device and a second semiconductor device, for which the first and second semiconductor devices, respectively, overlap a portion of the interposer and a portion of the power module and couple to a top surface of the interposer and a top surface of the power module.

Example 10 may include the electronic assembly of example 9 and/or any other example disclosed herein, for which the interposer comprises a substrate and a redistribution layer on the substrate.

Example 11 may include the electronic assembly of example 10 and/or any other example disclosed herein, for which the first and second semiconductor devices are coupled to each other through the redistribution layer.

Example 12 may include the electronic assembly of example 9 and/or any other example disclosed herein, for which the first and second semiconductor devices are coupled to the interposer through a plurality of solder bumps and to the power module through a solder layer.

Example 13 may include the electronic assembly of example 12 and/or any other example disclosed herein, for which the solder bumps each have a first width, and the solder layer has a second width, the second width being greater than the first width.

Example 14 provides an interposer, including a substrate comprising a plurality of through interposer vias and two openings extending through the substrate, and two power modules, each power module being arranged in one of the two openings, respectively, in the interposer, wherein each power module comprises a plurality of interconnects, the plurality of interconnects including a first interconnect coupled to a first voltage and a second interconnect coupled to a second voltage.

Example 15 may include the interposer of example 14 and/or any other example disclosed herein, for which at least one of the power modules extends between a top surface and bottom surface of the interposer.

Example 16 may include the interposer of example 14 and/or any other example disclosed herein, for which at least one of the power modules extends beyond a top surface of the interposer.

Example 17 may include the interposer of example 14 and/or any other example disclosed herein, further including a redistribution layer on the substrate.

Example 18 provides a method including providing an interposer including a plurality of through interposer vias, forming an opening through the interposer, arranging a power module in the opening in the interposer, in which the power module includes a plurality of interconnects including a first interconnect coupled to a first voltage and a second interconnect coupled to a second voltage, and attaching the interposer to a package substrate.

Example 19 may include the method of example 18 and/or any other example disclosed herein, for which the first interconnect and/or the second interconnect includes a plurality of conductive planes extending horizontally between a top surface and a bottom surface of the power module.

Example 20 may include the method of example 18 and/or any other example disclosed herein, for which before attaching the interposer to the package substrate, the method further includes coupling a first semiconductor device and a second semiconductor device, respectively, to a top surface of the interposer and a top surface of the power module.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. An electronic assembly, comprising:
a package substrate with a top substrate surface;
an interposer coupled to the package substrate at the top substrate surface, the interposer comprising a plurality of through interposer vias and an opening extending through the interposer; and
a power module arranged in the opening in the interposer and coupled to the package substrate at the top substrate surface, wherein the power module comprises a plurality of interconnects including a first interconnect coupled to a first voltage and a second interconnect coupled to a second voltage.

2. The electronic assembly of claim 1, wherein the first interconnect and/or the second interconnect comprises a plurality of conductive planes extending horizontally between a top surface and a bottom surface of the power module.

3. The electronic assembly of claim 2, wherein the plurality of conductive planes of the first interconnect is isolated from the plurality of conductive planes of the second interconnect by a dielectric material.

4. The electronic assembly of claim 3, wherein the dielectric material is epoxy mold compound, Bismaleimide-Triazine epoxy resin or silicone.

5. The electronic assembly of claim 2, wherein the plurality of conductive planes comprises a conductive plane with a thickness of 30 μm or greater.

6. The electronic assembly of claim 1, wherein the power module extends between a top surface and bottom surface of the interposer.

7. The electronic assembly of claim 1, wherein the power module extends beyond a top surface of the interposer.

8. The electronic assembly of claim 1, wherein the first voltage comprises a reference voltage, and wherein the second voltage comprises a power supply voltage.

9. The electronic assembly of claim 1, further comprising a first semiconductor device and a second semiconductor device, wherein the first and second semiconductor devices, respectively, overlap a portion of the interposer and a portion of the power module and couple to a top surface of the interposer and a top surface of the power module.

10. The electronic assembly of claim 9, wherein the interposer comprises a substrate and a redistribution layer on the substrate.

11. The electronic assembly of claim 10, wherein the first and second semiconductor devices are coupled to each other through the redistribution layer.

12. The electronic assembly of claim 9, wherein the first and second semiconductor devices are coupled to the interposer through a plurality of solder bumps and to the power module through a solder layer.

13. The electronic assembly of claim 12, wherein the solder bumps each have a first width, and the solder layer has a second width, the second width being greater than the first width.

14. An interposer, comprising:
a substrate comprising a plurality of through interposer vias and two openings extending through the substrate; and
two power modules, each power module being arranged in one of the two openings, respectively, in the interposer, wherein each power modules comprises a plurality of interconnects, the plurality of interconnects comprises a first interconnect coupled to a first voltage and a second interconnect coupled to a second voltage.

15. The interposer of claim 14, wherein at least one of the power modules extends between a top surface and a bottom surface of the interposer.

16. The interposer of claim 14, wherein at least one of the power modules extends beyond a top surface of the interposer.

17. The interposer of claim 14, further comprising a redistribution layer on the substrate.

18. A method, comprising:
providing an interposer comprising a plurality of through interposer vias;
forming an opening through the interposer;
arranging a power module in the opening in the interposer, wherein the power module comprises a plurality of interconnects including a first interconnect coupled to a first voltage and a second interconnect coupled to a second voltage; and
attaching the interposer to a package substrate.

19. The method of claim 18, wherein the first interconnect and/or the second interconnect comprises a plurality of conductive planes extending horizontally between a top surface and a bottom surface of the power module.

20. The method of claim 18, wherein before attaching the interposer to the package substrate, the method further comprises coupling a first semiconductor device and a second semiconductor device, respectively, to a top surface of the interposer and a top surface of the power module.
